(19) United States
(12) Patent Application Publication
(10) Pub. No.: US 2026/0104440 A1
(43) Pub. Date: Apr. 16, 2026

(54) CURRENT SENSOR

(71) Applicant: Renesas Electronics Corporation, Tokyo (JP)

(72) Inventor: Louis Richard WRAY, Dusseldorf (DE)

(73) Assignee: Renesas Electronics Corporation, Tokyo (JP)

(21) Appl. No.: 18/917,579

(22) Filed: Oct. 16, 2024

(51) Int. Cl. G01R 19/25; G01R 19/00; G01R 19/02; G01R 33/07; G01R 33/09

(52) U.S. Cl. CPC G01R 19/2506; G01R 19/003; G01R 19/02; G01R 33/07; G01R 33/09

(57) ABSTRACT

A current sensor for use with a current carrying conductor, the current sensor including: a magnetic field sensing element; a circuit coupled to the magnetic field sensing element and configured to provide a first signal associated with a current value via the magnetic sensing element, the current value having an unknown error; and a processor configured to execute a machine learning algorithm to generate an adjusted current value.

The present disclosure relates a current sensor for use with a current carrying conductor. In particular, it relates to a current sensor for use with a current carrying conductor for electrical metering.

### BACKGROUND

Currents sensors may be used for various applications to sense a current passing through a conductor. For the purpose of billable electrical metering, the current needs to be measured with a high degree of accuracy to match legally enforced industry standards such as those outlined by the International Electrotechnical Commission (IEC), International Organisation or Legal Metrology (OIML) and American National Standards Institute (ANSI) bodies. A typical current sensor topology includes a Rogowski coil placed near a current carrying conductor, the coil is connected to circuitry such that a generated voltage across the coil can be amplified and measured and thus the current through the conductor calculated. However, such topologies introduce non-linear errors to the current measurements.

These errors need to be compensated for, so that the electrical meter complies with relevant industry standards bodies. In most cases electrical meters need to work across a broad dynamic range, for example a typical operating range of 0.1 Amps to 100 Amps, therefore methods for adjusting the errors need to be applicable across a wide range of currents. Previously, techniques such as look-up tables or regression algorithms have been used. However, look-up tables suffer from being memory intensive and hence more expensive to implement. Regression algorithms require a lot of human and processing time to implement.

It is an object of the disclosure to address one or more of the above mentioned limitations.

### SUMMARY

According to a first aspect of the disclosure, there is provided a current sensor for use with a current carrying conductor, the current sensor comprising: a magnetic field sensing element; a circuit coupled to the magnetic field sensing element and configured to provide a first signal associated with a current value via the magnetic sensing element, the current value having an unknown error; and a processor configured to execute a machine learning algorithm to generate an adjusted current value.

For instance, the magnetic field sensing element comprises an inductor. The inductor may be a Rogowski coil.

For instance, the first signal may be a time varying signal.

Optionally, the machine learning algorithm comprises a plurality of sub-algorithms, each sub-algorithm being associated with a pre-determined range of current values; and wherein the processor is configured to select a sub-algorithm to be executed based on the current value.

Optionally, each sub-algorithm is trained using a set of training data; wherein each training data in the set comprises a pair of input and output training values.

Optionally, for each pair, the input training value is a current value having an unknown error and the output training value is a known reference current value without error.

Optionally, each sub-algorithm is trained using a selected training algorithm, the selected training algorithm comprising at least one of a forward pass algorithm, a backpropagation algorithm and a cost function algorithm.

Optionally, the pre-determined ranges of current values are independent and non-overlapping; or wherein the pre-determined ranges of current values are partially overlapping.

Optionally, comprising a memory configured to store the machine learning algorithm.

Optionally, the sub-algorithms comprise an artificial neural network.

Optionally, each sub-algorithm comprises a multi-layer perceptron comprising a set of weights, a set of biases and an activation function.

Optionally, the activation function comprises a rectified linear unit function.

Optionally, the magnetic field sensing element comprises at least one of a Rogowski coil, a current transformer, a magnetic resistor sensor and a Hall sensor.

Optionally, the magnetic field sensing element is configured to sense a time varying magnetic field signal and output this signal to the circuit.

Optionally, the circuit comprises: an amplifier configured to amplify the time varying magnetic field signal; and a converter configured to convert the time varying magnetic field signal to obtain the first signal and output the first signal to the processor.

For instance, the converter may be an analogue-to-digital converter.

Optionally, the processor comprises: an integrator, configured to integrate the first signal; and a calculator configured to receive the integrated first signal and calculate the root mean squared value of the integrated first signal; whereby the root mean squared value of the integrated first signal is the current value having an unknown error, wherein the calculator is further configured to output the current value having unknown error to the machine learning algorithm.

According to a second aspect of the disclosure, there is provided an apparatus comprising: a current carrying conductor; and a current sensor according to the first aspect.

Optionally, the apparatus is an electrical meter configured to measure an amount of current entering a load.

It will be appreciated that the apparatus of the second aspect may include providing and/or using features set out in the first aspect and can incorporate other features as described herein.

According to a third aspect of the disclosure, there is provided a method of monitoring a current value, the method comprising: providing a current sensor as claimed in any one of the claims 1 to 14, obtaining using the circuit coupled to the magnetic field sensing element, a first signal associated with a current value having an unknown error; and executing, using a processor, a machine learning algorithm to generate an adjusted current value.

Optionally, the machine learning algorithm comprises a plurality of sub-algorithms, each sub-algorithm being associated with a pre-determined range of current values; and the method further comprising selecting a sub-algorithm to be executed based on the current value.

It will be appreciated that the method of the third aspect may include providing and/or using features set out in the first aspect and/or second aspect and can incorporate other features as described herein.

### BRIEF DESCRIPTION OF THE DRAWINGS

The disclosure is described in further detail below by way of example and with reference to the accompanying drawings, in which:

FIG. 1 is an example diagram of a current sensor for use with a current carrying conductor according to the present disclosure;

FIG. 2 is an example diagram of a sub-algorithm according to the present disclosure;

FIG. 3 is a plot of a rectified linear unit function that can be used with the sub-algorithm of FIG. 2;

FIG. 4 is a plot showing an example set of training data that can be used to train the sub-algorithm of FIG. 2;

FIG. 5 is an example implementation of a trained sub-algorithm;

FIG. 6A is a plot showing raw current measurements obtained using three current sensors according to the prior art without adjustment/error compensation;

FIG. 6B is an exemplary plot showing the adjusted current values according to the present disclosure;

FIG. 7 is an example implementation of a circuit for use in the current sensor of FIG. 1;

FIG. 8 is an example implementation of a processor for use in the current sensor of FIG. 1;

FIG. 9 is an exemplary implementation of the current sensor of FIG. 1;

FIG. 10 is a schematic diagram of an apparatus provided with a current sensor according to the present disclosure;

FIG. 11 is an exemplary implementation of the apparatus of FIG. 10; and

FIG. 12 is a flow chart of an example method of adjusting a current value according to the present disclosure.

### DETAILED DESCRIPTION

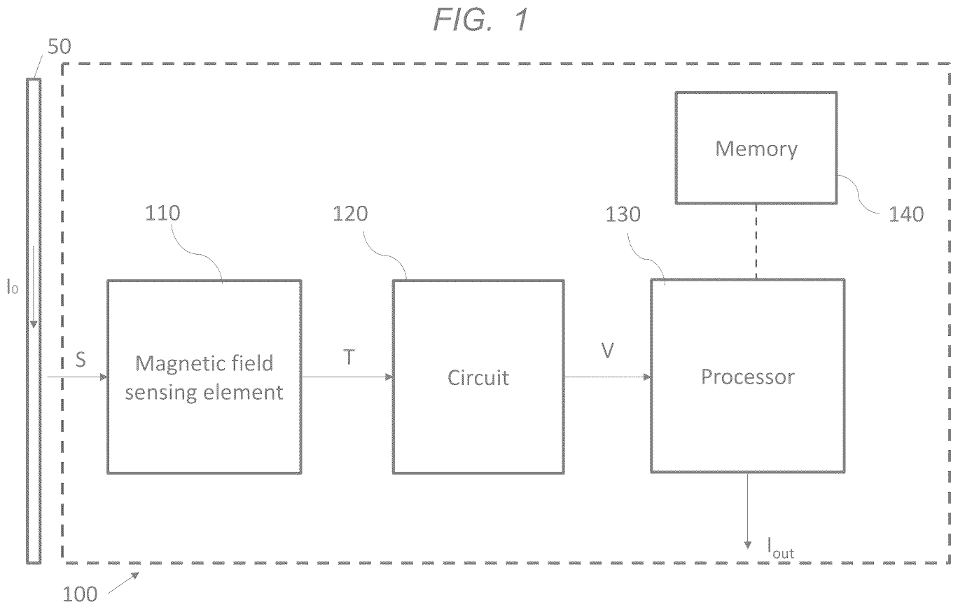

FIG. 1 is a diagram of a current sensor 100 for use with a current carrying conductor according to the present disclosure. The current sensor 100 comprises a magnetic field sensing element 110, a circuit 120 and a processor 130. The circuit 120 is coupled to the magnetic field sensing element 110. The current sensor 100 may further comprise a memory 140 coupled to the processor 130 for storing a machine learning algorithm executable by the processor 130.

In use the Magnetic field sensing element 110 is placed in close proximity with a conductor 50 carrying a current I₀. The magnetic field sensing element 110 is configured to sense a time varying magnetic field signal S and to output a translated signal T to the circuit 110. The translation from S to T may or may not include manipulation of the original signal, be it phase shifting, amplitude changes or otherwise. The magnetic field sensing element 110 may be implemented in different ways. For instance, the field sensing element 110 may be implemented as a Rogowski coil, a current transformer, a magnetic resistor sensor or a Hall sensor.

The circuit 120 is configured to provide a first signal associated with a current value of the current I₀ flowing through the conductor 50, and having an unknown error. For instance, the first signal may be a time varying signal, such as a time varying voltage signal V, which may be a digital signal. Therefore, the first signal V is dependent upon the time varying magnetic field signal S. The processor 130 is configured to receive the first signal V as an input, process it to generate a current value Iᵢₙ having an unknown error associated with it. This may be achieved via integration of the first signal The processor is further configured to execute a machine learning algorithm to generate an adjusted current value Iₒᵤₜ. The adjusted current value Iₒᵤₜ compensates for the unknown error value in the current value Iᵢₙ.

The machine learning ML algorithm may include a plurality of sub-ML-algorithms, simply referred to as sub-algorithms. For instance, each sub-algorithm may be associated with a pre-determined range of current values. For example, a first range of current values may be from 0.05 Amps to 1 Amps, a second range of current values may be from 1 Amps to 20 Amps and a third range of current values may be from 20 Amps to 80 Amps. It will be appreciated that different ranges of current values may be used. The ranges of current values may be independent and non-overlapping, alternatively they may be partially overlapping. When using sub-algorithms, the processor 130 is configured to select a sub-algorithm to be executed based on the current value Iᵢₙ. The memory 140, which is coupled to the processor 130, may be configured to store the plurality of sub-algorithms that may be executed by the processor 130. The machine learning algorithm and each sub-algorithm may be implemented as a neural network.

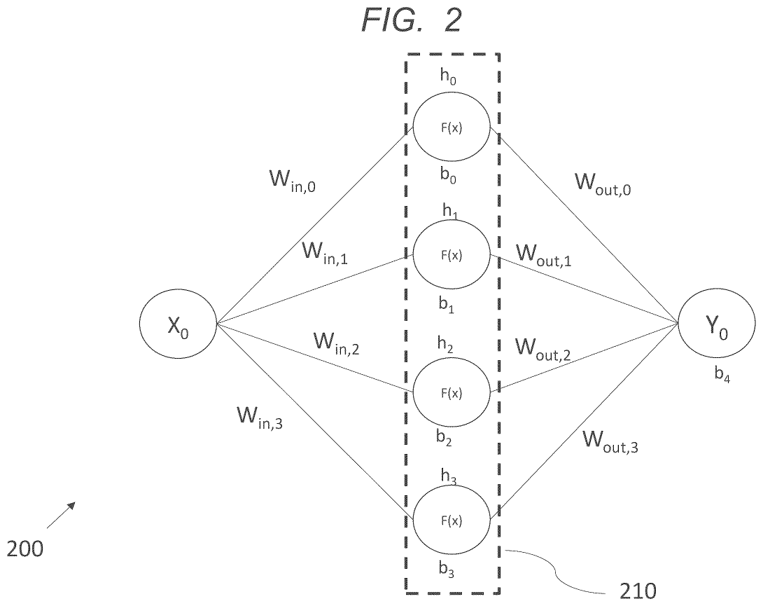

FIG. 2 is a diagram of a sub-algorithm 200 implemented as a neural network that may form one of the plurality of sub-algorithms. The sub-algorithm may be, for example, an entry level neural network such as multi-layer perceptron (MLP). The sub-algorithm 200 has a single input X₀, a single neuron layer 210 and a single output Y₀. The neuron layer 210 includes four nodes h₀, h₁, h₂, and h₃. The sub-algorithm 200 also includes several model parameters such as biases bᵢ and weight multipliers W_{in,i} and W_{out,i}.

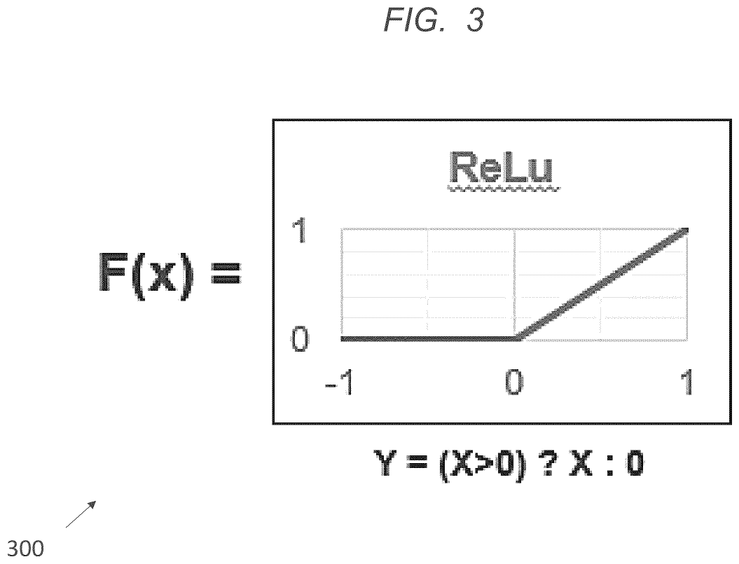

The single input X₀ is connected to each of the four nodes h₀, h₁, h₂, and h₃ by four different internode connections, each internode connection has a weight multiplier associated with it. These weight multipliers are labelled W_{in,0}, W_{in,1}, W_{in,2} and W_{in,3} in FIG. 2. At each node h₀, h₁, h₂, and h₃ in the neuron layer 210, a bias bᵢ and an activation function F(x) is applied to the sum of the nodes weighted inputs, which in this illustration is only one but may be more in multi-layer models. The activation function may be, for example, a rectified linear unit (ReLu) function which is shown in FIG. 3.

It will be appreciated that, the sub-algorithm 200 may be modified to include any number of inputs, any number of neuron layers and any number of nodes in the layers in accordance with the understanding of the skilled person.

Alternatively, other types of neural networks (other than MLP) may also be used for implementing the ML algorithm or sub ML algorithms. FIG. 3 is a plot of a rectified linear unit (ReLu) function. The ReLu function 300 works as follows: if the value at neuron hᵢ is less than or equal to zero, then F(xᵢ)=0, but if the value at the neuron hᵢ is greater than zero then F(Xᵢ)=Xᵢ, where xᵢ is the value that reaches neuron hᵢ. With reference to FIG. 2, the value xᵢ will be xᵢ=(X₀×W_{in,i})+bᵢ.

The ReLu function 300 provides the ability of the sub-algorithm to account for non-linear errors which are introduced when using a magnetic field sensing element 110 to sense the current I₀ through the current carrying conductor 50. However, other activation functions may be used in accordance with the understanding of the skilled person.

Returning to FIG. 2, each of the four nodes h₀, h₁, h₂, and h₃ are connected to the single output Y₀ by four internode connections. Each of the four internode connections has a weight multiplier associated with it. These weight multipliers are labelled W_{out,0}, W_{out,1}, W_{out,2} and W_{out,3}. The single output node Y₀ has an output node bias b₄ associated with it. In the context of the present disclosure, the single input X₀ would be the current value Iᵢₙ with an unknown error associated with it and the single output Y₀ would be the adjusted current value Iₒᵤₜ.

The sub-algorithm 200, which may be implemented as a MLP, is trained to linearise and adjust for errors introduced when using the magnetic field sensing element 130 to sense the current. In practice, to implement the sub-algorithm 200, a structure is first defined. The structure determines the number of nodes and their internode connections. Then the sub-algorithm 200 is trained. The training of the sub-algorithm is discussed in further detail below. The training of the sub-algorithm 200 optimises the model parameters to be used.

Once the sub-algorithm 200 has been trained, the weights and biases (model parameters) are optimised such that the sub-algorithm 200 accepts a current value Iᵢₙ having an unknown error and adjusts the current value Iᵢₙ to adjust for the error and output a “corrected” value Iₒᵤₜ. This “corrected” value is the adjusted current value Iₒᵤₜ, in other words the current value with the unknown error minimised or eliminated.

When implemented as part of the current sensor 100 of FIG. 1, the trained sub-algorithm 200 may be referred to as a regression model as it compensates, mathematically, the relationship between two variables. The two variables could be, for example, the current value Iᵢₙ and a known reference current value I_{acc}. The known reference current value I_{acc} may be a current which has been measured by a highly accurate sensing element.

Each sub-algorithm 200 is given a neural network structure and then is trained using a set of training data and a selected training algorithm to determine the optimised model parameters for the sub-algorithm.

Each of the training data in the set comprise a pair of input and output training values. The input training value may be, for example, raw data of a previously analysed system and the output training value will be the known corrected value for the raw data. The selected training algorithm comprises a forward pass algorithm, a backward propagation algorithm and a cost function algorithm. The forward pass algorithm, which may also be referred to as forward propagation, is the process of taking an input X0 and passing it through the neural layers of the sub-algorithm to generate an output Y0. Backward propagation algorithm, which may also be referred to as backward propagation of errors algorithm, is an algorithm that may be used for supervised learning of the neural network structure. The backward propagation algorithm calculates the gradient of the error, reported by the cost function, associated with the neural network with respect to the weights assigned to each internode connection and the biases at each node. The gradient of error calculated at each node indicates what proportion of the error the respective node is responsible for. The larger the gradient, the larger the error contribution and finally the larger the correction. This calculation is performed by starting from the last neural layer before the output Y0 and working backwards to the input X0. The cost function algorithm computes the difference between the networks predicted output and the target output. The cost function may be, for example, a log cosh function. The forward pass, backward propagation and cost function algorithms are commonly used algorithms in the field of machine learning and therefore variations may be implemented in accordance with the understanding of the skilled person.

In an exemplary implementation, the ML algorithm or sub-ML algorithm may be trained as follows. The set of training data may be performance data from a lab environment wherein currents have been passed through a high-accuracy current sensing system under test conditions. Therefore, the pair of input and output training values in this case will be current values I_{in,i} measured using a current sensor 100 as of FIG. 1 (input training values) and the high-accuracy currents I_{acc} (output training values) as measured using the high-accuracy system. As the adjustment required for the high-accuracy currents I_{acc} is already known, the sub-algorithm 200 can be trained. This training is done through feeding the input training data I_{in,i} to the sub-algorithm 200 which is implemented with an initial set model parameters. The weights and biases of the initial set of model parameters are randomly assigned a value between −1 and 1. The output data I_{out,1} may be considered a prediction of the adjusted current value. This value is compared to the high-accuracy current value I_{acc}. The difference between the estimated output I_{out,i} and the known value I_{acc}, computed by the cost function, is used to adjust the model parameters of the sub-algorithm 200 via backward propagation. This exercise is performed iteratively with large, shuffled data sets and may be automated with a computer program. At the end of the training, the sub-algorithm 200 has optimised the model parameters and can take in a current value with unknown error Iᵢₙ and compensate this value as closely as possible to the corrected/adjusted value Iₒᵤₜ.

Different sub-algorithms are then trained on a different range of current values. By using sub-algorithms 200 for different ranges of current values, the non-linearities can be corrected more efficiently without increasing the computational processing time or the memory required.

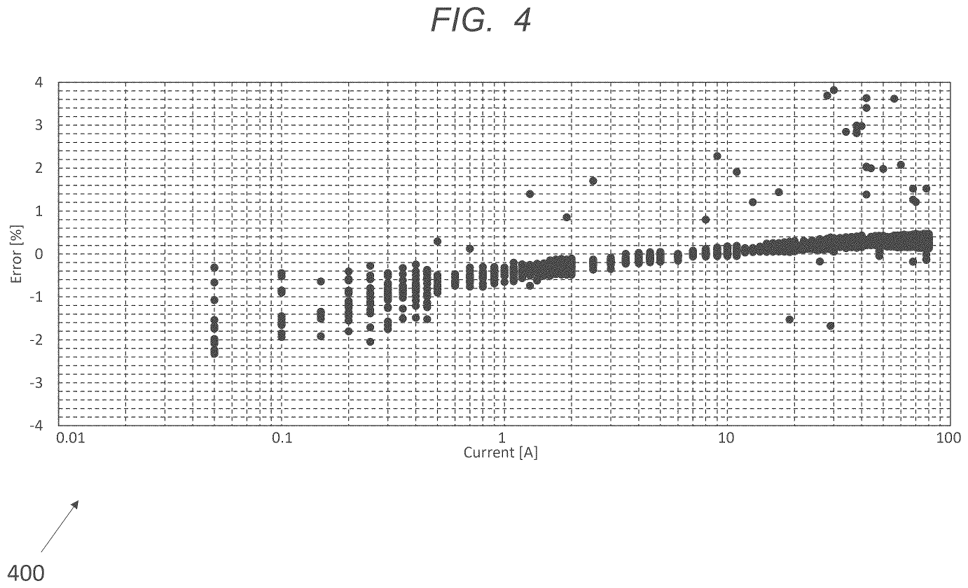

FIG. 4 is a plot 400 showing an example set of training data according to the present disclosure. This example set of training data can be used to train the sub-algorithm 200 of FIG. 2. The training data comprises measurements that were made across 12 different sample devices. The plot 400 shows the current versus the error in the uncompensated measurement. The error is the percentage difference between the input current and the current that was actually measured by a sample device.

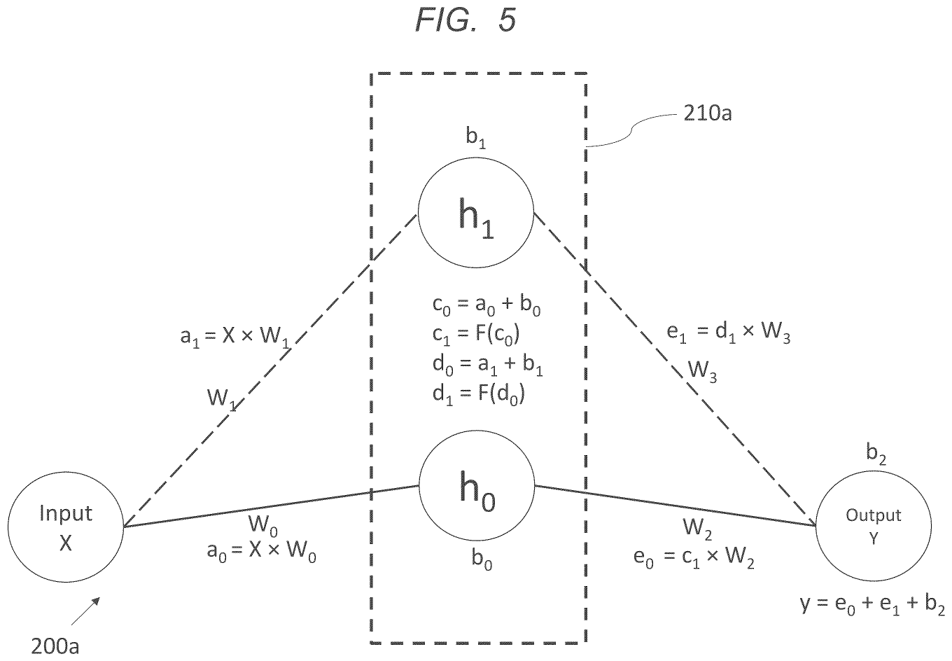

FIG. 5 is an example implementation of a trained sub-algorithm 200a. The trained sub-algorithm 200a may be one of the plurality of sub-algorithms that form part of the machine learning algorithm executed by processor 130 of FIG. 1. In this example, the neuron layer 210a has two nodes. The first node h₀ has a bias b₀ and the second node h₁ has a bias b₁. Mathematically speaking, sub-algorithm 200a is implemented on an input X by multiplying the outputs of each node by the weight of the internode connections and then summing the values arriving at each node together with the addition of the node bias—the single input node has a fixed bias of 0 and no activation function is performed, while the output node has a non-zero bias and no activation is performed.

For input X, following the internode connections marked with a solid line, coefficient a₀ is calculated by multiplying input X by the weight multiplier W₀. The coefficient a₀ is then used to calculate coefficient c₀ as c₀=a₀+b₀, where b₀ is the bias for the first node h₀ in the neuron layer 210a. The activation function, for example the ReLu function, is then applied to get coefficient c₁, with c₁=F(c₀). The weight multiplier W₂ is then applied to coefficient c₁ to obtain coefficient e₀. For input X, now following the internode connections marked with a dashed line, coefficient a₁ is calculated by multiplying input X by the weight multiplier W₁. Next, coefficient a₁ is used to calculate coefficient d₀, whereby d₀=a₁+b₁ and where b₁ is the bias for the second node h₁ in the neuron layer 210a. The activation function, for example the ReLu function, is then applied to coefficient do to obtain coefficient d₁ with, d₁=F(d₀). Finally, the weight multiplier W₃ is applied to get the sixth coefficient e₁. The output Y of sub-algorithm 200a is then given by Y=e₀+e₁+b₂, where b₂ is the output node bias.

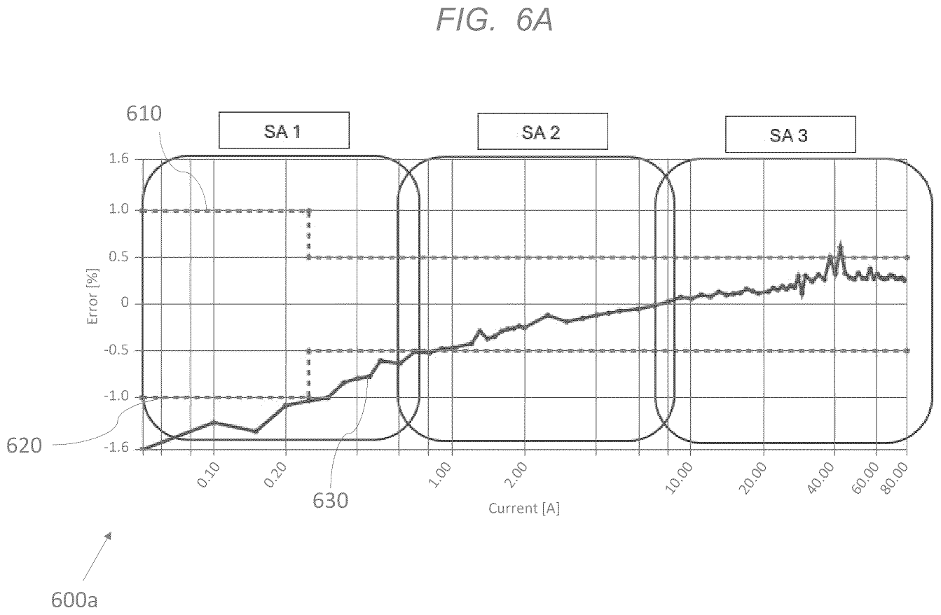

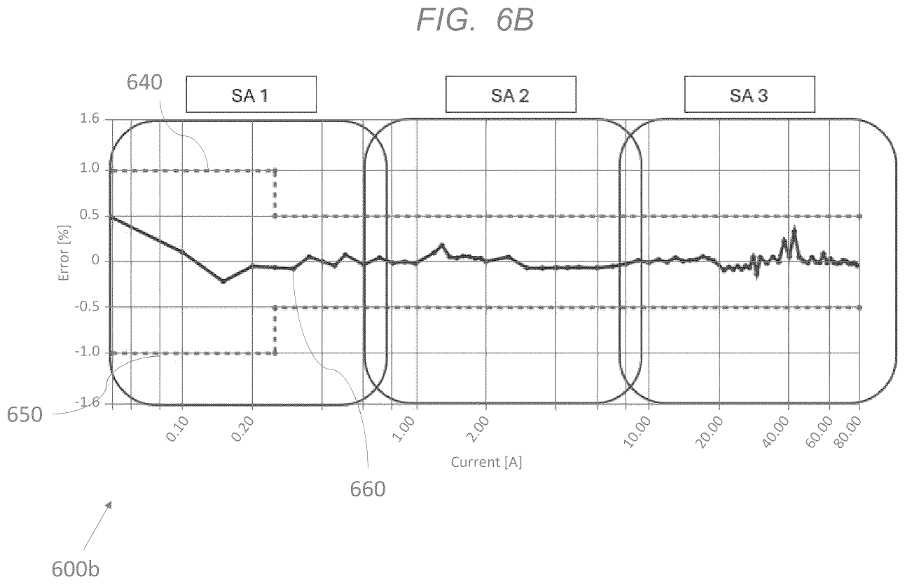

FIG. 6A is a plot 600a showing the raw current measurements obtained using three current sensors according to the prior art and without adjustment/error compensation. In other words, FIG. 6A is showing the current values Iᵢₙ with the unknown error associated with said values. The current measurements are provided for three current ranges.

The two horizontal dashed lines 610 and 620 show the accuracy tolerance as set by standards bodies for electrical metering, in this example a tolerance of ±1% accuracy at the low end of the dynamic range of operation and ±0.5% for the rest of the dynamic range of operation was set. The current sensed by the current sensor 100 needs to fall within these accuracy tolerances. The other data line labelled 630 is a current sensor performance. It can be seen that when going below 1 Amp or above 40 Amps the non-linear errors introduced by the magnetic field sensing element 130 are outside the accuracy tolerances.

FIG. 6B is an exemplary plot 600b showing the current measurements obtained using current sensor 100 according to the present disclosure with adjustment/error compensation. In this example, the current sensor 100 is being used to measure the current for an electrical meter, therefore it must comply with a specific standard body accuracy. The two horizontal lines 640 and 650 show the accuracy tolerance as set by standards bodies for electrical metering, in this example a tolerance of ±1% accuracy at the low end of the dynamic range of operation and ±0.5% for the rest of the dynamic range of operation was set. The data line labelled 660 shows the adjusted current values obtained using the current sensor 100 of the present disclosure. The data that form the data line 660 were obtained through a simulation. As can be seen, at all values of current, the adjusted current values lie within the accuracy tolerances.

The machine learning algorithm has three sub-algorithms labelled SA 1, SA 2 and SA 3 which each cover three different ranges of current. There is a small overlap in the current ranges to ensure that rapid switching between models does not impact performance. This hysteresis also ensures that each model does not have a weak operating region.

The dynamic range of the operating region of the current carrying conductor is split into an arbitrary but fixed number of areas of operation. For each area, a model is assigned and trained. The current value Iᵢₙ determines which model is used. There are benefits to employing a segmented model. First, a lower processing time is required when compared to fewer larger models. Second, the memory is reduced when compared to creating a single model with sufficient complexity to cover complex error curves.

The example shown in FIG. 6B used localised MLP models as the sub-algorithms to correct the non-linearities in current measured by the magnetic field sensing element 130 of current sensor 100. These non-linearities may also arise in other components of the current sensor 100, for example in the circuit 120. The split model approach used in current sensor 100 allows for fine tuning for the adjustment of the current value across a dynamic range of current values whilst keeping complexity, loading and memory usage at a minimum. Each model is trained individually on a given range of current values, and the model used for adjustment is decided based on the current value Iᵢₙ. Further advantages of the current sensor 100 of the present disclosure is that there is minimum development complexity upon implementation due to the inherent nature of machine learning when training models on system. Further, as continuous error correction is applied, no quantization error is introduced from the algorithm itself.

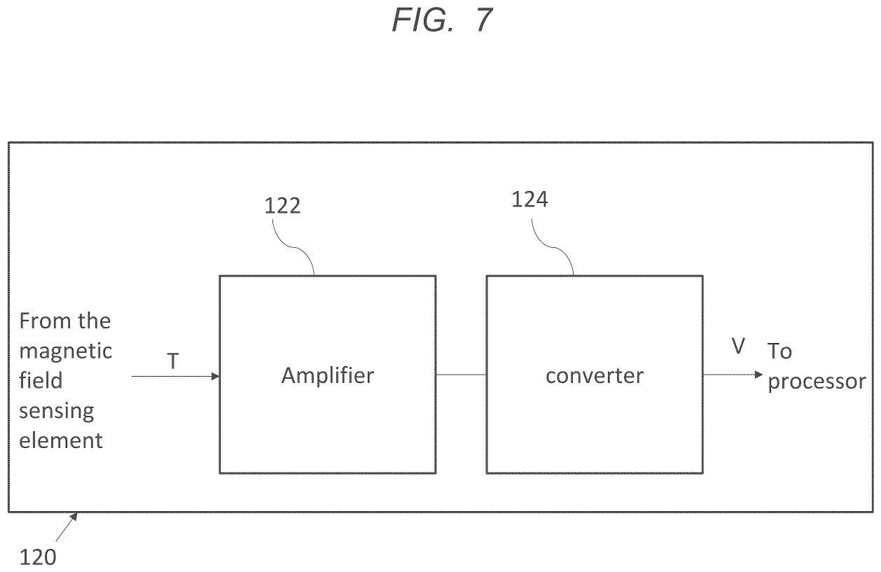

FIG. 7 is an example implementation of a circuit 120 for use in the current sensor of FIG. 1. The circuit 120 includes an amplifier 122 and a converter 124. Each of the amplifier 122 and converter 124 may comprise further components, such as an analogue-to-digital converter (ADC).

The amplifier 122 is configured to receive the translated time varying magnetic field signal T from the magnetic field sensing element 110. The amplifier 122 is further configured to amplify the signal T to generate substantial analogue signal and output the analogue signal to the converter 124. The converter 124 converts this to the first signal V. The first signal may be a representative digital code V to be sent to the processor 130 for further processing.

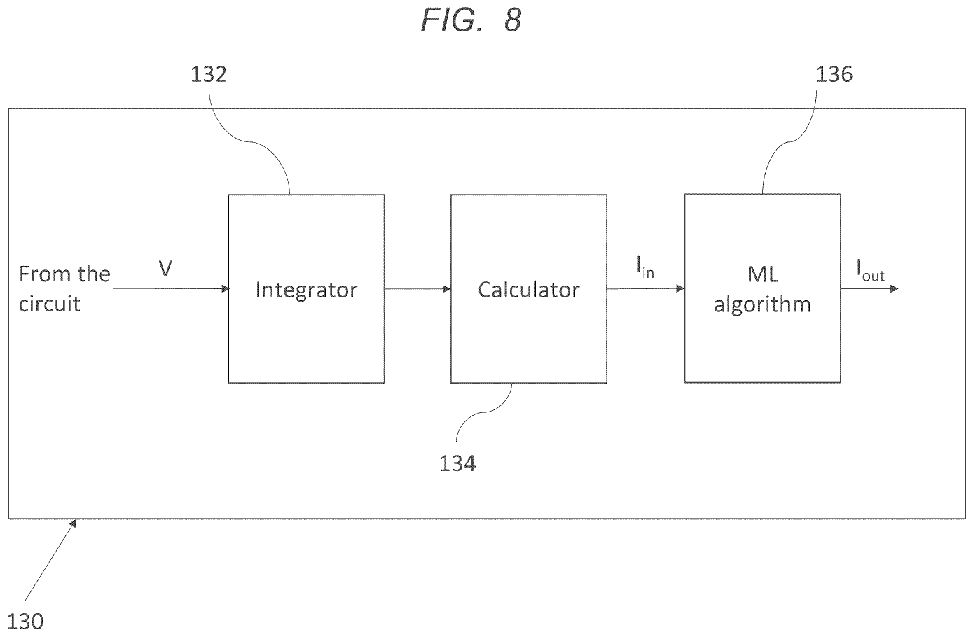

FIG. 8 is an example implementation of a processor 130 for use in the current sensor of FIG. 1. The processor 130 includes an integrator 132, a calculator 134 and a correction algorithm 136. Each of the integrator 132, calculator 134 and the correction algorithm 136 may comprise further components.

The integrator 132 is configured to receive the first signal V and integrate the signal. The integration is performed because the translated time varying magnetic field signal T is proportional to the derivative of signal S. By integrating the first signal V, the derivative relationship is removed. The integrated first signal is then buffered and outputted to the calculator 134. The calculator 134 is configured to calculate the root mean squared value of the integrated and buffered first signal V. The root mean squared value of the digital signal is equal to the current value Iᵢₙ which has an unknown error. The current value Iᵢₙ is then passed through the machine learning (ML) algorithm that has been previously described to generate the adjusted current value Iₒᵤₜ which compensates for the unknown error value in the current value Iᵢₙ.

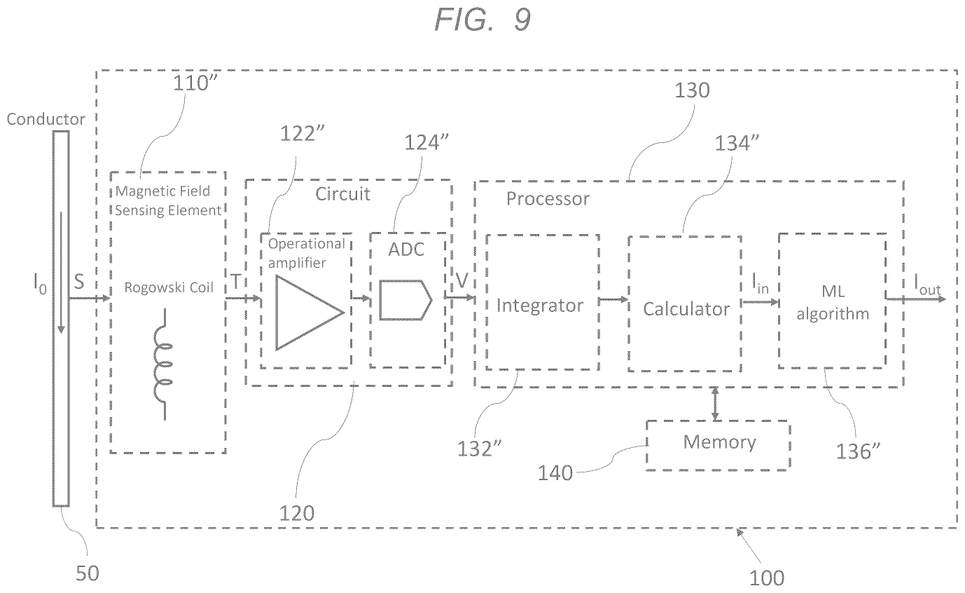

FIG. 9 is an exemplary implementation of current sensor 100 of FIG. 1. The current sensor 100 comprises a magnetic field sensing element 110″. In the example embodiment shown in this figure, the magnetic field sensing element 110″ is a Rogowski coil. In alternative embodiments, the magnetic field sensing element 110″ may comprise a current transformer, a magnetic resistor sensor and/or a Hall sensor. The magnetic field sensing element 110″ is coupled to a circuit 120. The circuit 120 is an exemplary implementation of the circuit shown in FIG. 7. The circuit 120 comprises an amplifier 122″ and a converter 124″. In this exemplary embodiment, the amplifier 122″ is implemented as an operational amplifier and the converter 124″ is an analogue-to-digital converter (ADC). The current sensor 100 further comprises a processor 130 and a memory 140. The processor 130 is an exemplary implementation of the processor shown in FIG. 8. The processor comprises an integrator 132″, a calculator 134″ and a ML algorithm 136″. The ML algorithm 136″ is the machine learning algorithm that has been previously described in this document and its description will not be repeated here. In this example embodiment, the integrator 132″ is configured to execute Runge-Kutta 4th order method. In alternative embodiments other integration methods may be used.

In operation, the magnetic field sensing element 110″ is placed in close proximity with a conductor 50 carrying a current I₀. The magnetic field sensing element 110″ is configured to sense a time varying magnetic field signal S and to output a translated signal T to the circuit 110. The operational amplifier 122″ is configured to receive the translated time varying magnetic field signal T from the magnetic field sensing element 110″. The operational amplifier 122″ is further configured to amplify the signal T to generate substantial analogue signal and output the analogue signal to the ADC 124″. The ADC 124″ converts this signal to the first signal. In this example embodiment, the first signal is a representative digital code V to be sent to the integrator 132″. The integrator 132″ then integrates the digital code V using the Runge-Kutta fourth order method. The Runge-Kutta fourth order method is performed using these equations:

$${k}_{1} = hf ( {x}_{n} , {y}_{n} )$$

$${k}_{2} = hf ( {x}_{n} + \frac{h}{2} , {y}_{n} + \frac{{k}_{1}}{2} )$$

$${k}_{3} = hf ( {x}_{n} + \frac{h}{2} , {y}_{n} + \frac{{k}_{2}}{2} )$$

$${k}_{2} = hf ( {x}_{n} + h , {y}_{n} + {k}_{3} )$$

$${y}_{n + 1} = {y}_{n} + ( \frac{1}{6} ) ( {k}_{1} + 2 {k}_{2} + 2 {k}_{3} + {k}_{4} )$$

Once the integration has been performed, the integrator then passes the integrated digital signal to the calculator 134″. The calculator 134″ calculates the root mean squared value of the integrated digital signal V:

$$RMS = \sqrt{( \frac{1}{N} ) \cdot {\sum }_{i = 1}^{N} {x}_{i}^{2}}$$

The root mean squared value is equal to the current value Iᵢₙ which has an unknown error. This current value Iᵢₙ is passed through the ML algorithm 136″, which has been previously described, which provides the generation of the adjusted current value Iₒᵤₜ which compensates for the unknown error value in the current value Iᵢₙ.

The adjusted current value Iₒᵤₜ may then be used for power computations for the purposes of electricity meter measurements or other applications.

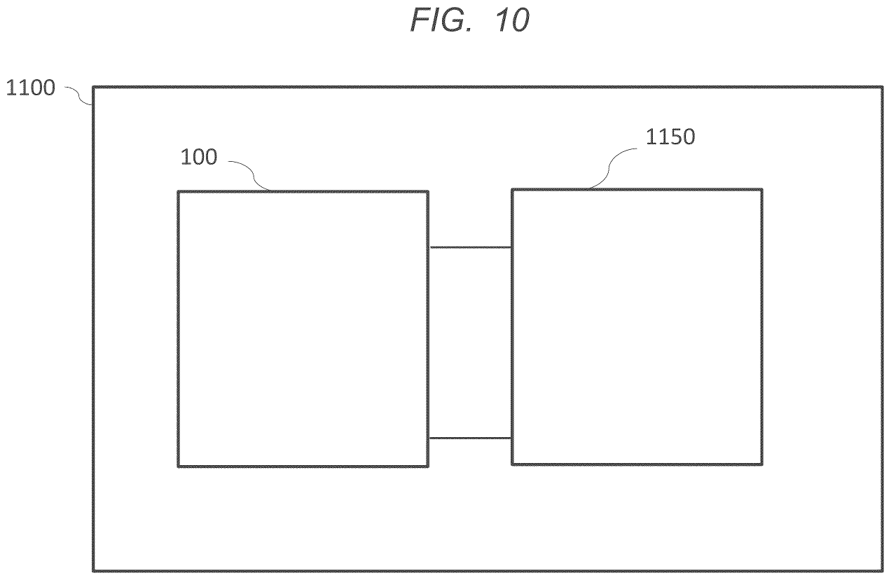

FIG. 10 is a schematic diagram of an apparatus 1100 provided with a current sensor as shown in FIG. 1. The apparatus 1100 includes a current carrying conductor 1150 coupled to a current sensor 100 according to present disclosure. Hence, the same labelling has been kept and components are taken to have the same functionality and meaning.

The current sensor 100 is configured to sense a current value Iᵢₙ across the current carrying conductor 1150 and generates an adjusted current value Iₒᵤₜ. The apparatus 1100 may be, for example, an electrical meter configured to measure the amount of current entering a load. The load may be associated with a building or an electric vehicle. Therefore, in the case where the load is for a building, the adjusted current value Iₒᵤₜ is used to calculate the power a building is using and therefore generate a corresponding monetary charge.

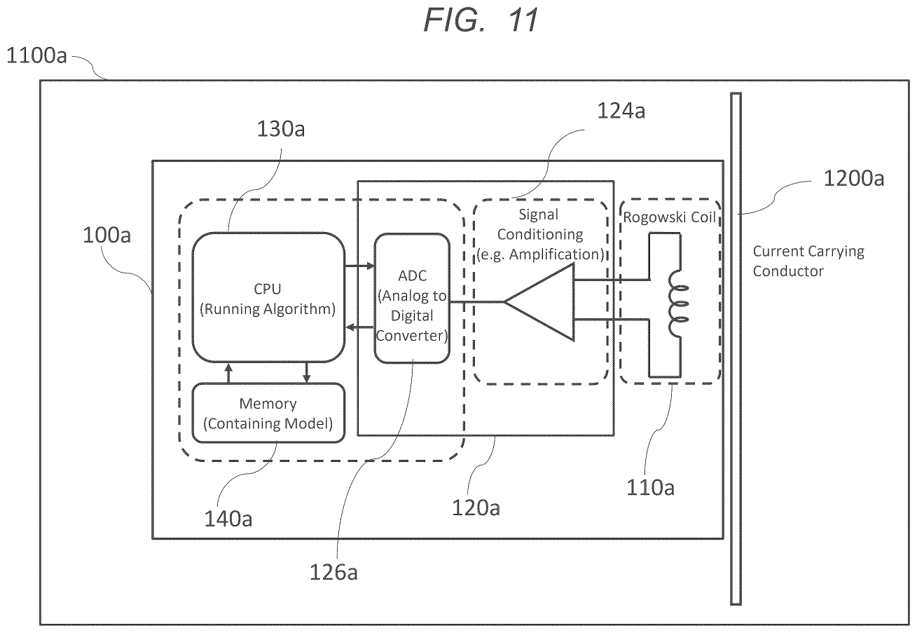

FIG. 11 is an exemplary implementation of the apparatus 1100 of FIG. 10. The apparatus 1100a comprises a current carrying conductor 1200a coupled to a current sensor 100a configured for use with the current carrying conductor 1150a. The current sensor 100a is an example implementation of the current sensor 100 of FIG. 1.

The current sensor 100a comprises a magnetic field sensing element 110a. In the example embodiment of FIG. 11, the magnetic field sensing element 110a is a Rogowski coil. In other embodiments the magnetic field sensing element 110a may comprise a current transformer, a magnetic resistor sensor and/or a Hall sensor. The magnetic field sensing element 110a is coupled to a circuit 120a. In this exemplary embodiment, the circuit 120a comprises a signal conditioner 124a and an ADC 126a′. Finally, the current sensor 100a also comprises a processor 130a and a memory 140a.

In operation, the current passing through the current carrying conductor 1150a induces a time-varying magnetic field S′. The changing magnetic field induces an analogue voltage signal in the magnetic field sensing element 110a. The analogue voltage signal is then passed through to the circuit 120a. In this example, the circuit 120a includes a signal conditioner 124a and an ADC 126a′. It will be appreciated that the circuit 120a may comprise additional or different components such as an integrator. The signal conditioner 124a is configured to amplify the analogue voltage signal. The ADC 126a′ is configured to convert the amplified analogue voltage signal to a digital voltage signal. This digital voltage signal could be, for example, a 24-bit code. The ADC 126a′ may also apply a high pass filter to the digital voltage signal to remove any DC offset that may be present in the signal. The digital voltage signal is then integrated and buffered to remove the derivative relationship between the Rogowski generated voltage and the current through the current carrying conductor. Finally, the root mean squared value of the signal is calculated which provides the current value Iᵢₙ. This current value represents the amount of current which is flowing through the current carrying conductor 1150a. It has an unknown error associated with it. This unknown error is non-linear. Once the current value Iᵢₙ has been obtained the processor 130a then executes a machine learning algorithm to generate an adjusted current value Iₒᵤₜ.

The machine learning algorithm may comprise a plurality of sub-algorithms. Each sub-algorithm is associated with a pre-determined range of current values. For example, a first range of current values may be from 0.05 Amps to 1 Amps, a second range of current values may be from 1 Amps to 20 Amps and a third range of current values may be from 20 Amps to 80 Amps. It will be appreciated that in other embodiments, different ranges of current values may be used in accordance with the understanding of the skilled person. In some embodiments, the ranges of current values may be independent and non-overlapping whilst in other embodiments they may be partially overlapping. The processor 130 is configured to select the sub-algorithm to be executed based on the current value Iᵢₙ. The memory 140a is configured to store the plurality of sub-algorithms.

The buffering and integration of the digital voltage signal as well as the calculation of the root mean squared value may be performed by the circuit 120a or the processor 130a.

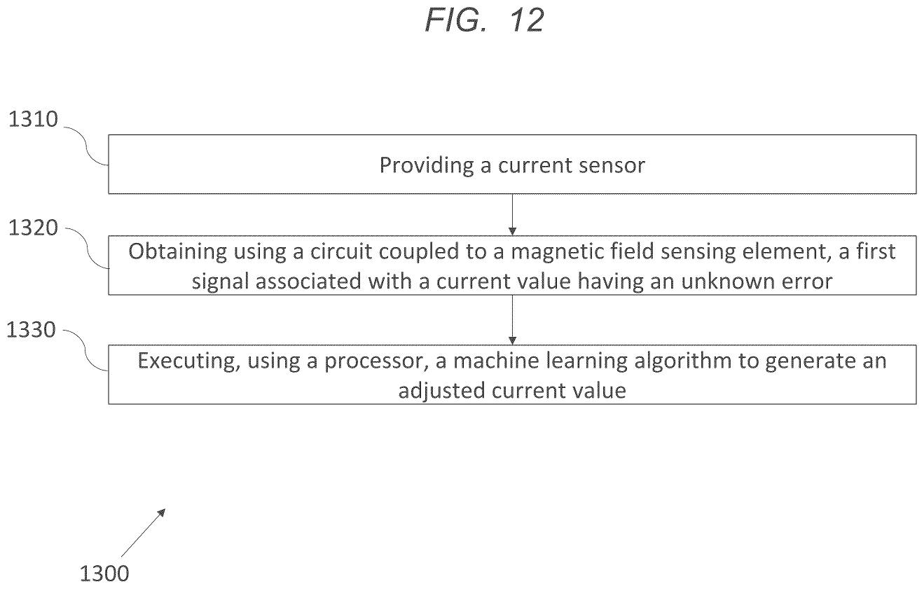

FIG. 12 is a flow chart 1300 of an example method of monitoring a current value in accordance with the present disclosure. The method comprises steps 1310, 1320 and 1330. The method may be applied to any current sensor embodiment of the present disclosure.

First, at step 1310, a current sensor is provided. The current sensor may be any of the example embodiments of the present disclosure.

During step 1310, a first signal associated with a current value is obtained. The current value has an unknown error. The first signal associated with a current value is obtained by using a circuit coupled to a magnetic field sensing element. During step 1330, a machine learning algorithm is executed using a processor in order to generate an adjusted current value.

The machine learning algorithm may comprise a plurality of sub-algorithms. Each sub-algorithm may be associated with a pre-determined range of current values. For example, a first range of current values may be from 0.05 Amps to 1 Amps, a second range of current values may be from 1 Amps to 20 Amps and a third range of current values may be from 20 Amps to 80 Amps. It will be appreciated that different ranges of current values may be used. The ranges of current values may be independent and non-overlapping whilst in other embodiments they may be partially overlapping.

The current sensor of the present disclosure permits to compensate for the non-linear errors in a sensed current in a fast and efficient way.

As discussed above the current sensor of the present disclosure may be used with a current carrying conductor for electrical metering purposes. It will be appreciated that, the current sensor may be also used for other applications. For example, the current sensor of the present disclosure may also be used to measure the amount of current entering an electric vehicle during charging.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

What is claimed is:

1. A current sensor for use with a current carrying conductor, the current sensor comprising:
a magnetic field sensing element;
a circuit coupled to the magnetic field sensing element and configured to provide a first signal associated with a current value via the magnetic sensing element, the current value having an unknown error; and
a processor configured to execute a machine learning algorithm to generate an adjusted current value.

2. The current sensor according to claim 1, wherein the machine learning algorithm comprises a plurality of sub-algorithms, each sub-algorithm being associated with a pre-determined range of current values; and wherein the processor is configured to select a sub-algorithm to be executed based on the current value.

3. The current sensor according to claim 2, wherein each sub-algorithm is trained using a set of training data; and wherein each training data in the set comprises a pair of input and output training values.

4. The current sensor according to claim 3, wherein for each pair, the input training value is a current value having an unknown error and the output training value is a known reference current value without error.

5. The current sensor according to claim 2, wherein each sub-algorithm is trained using a selected training algorithm, the selected training algorithm comprising at least one of a forward pass algorithm, a backpropagation algorithm and a cost function algorithm.

6. The current sensor according to claim 2, wherein the pre-determined ranges of current values are independent and non-overlapping; or wherein the pre-determined ranges of current values are partially overlapping.

7. The current sensor according to claim 1, comprising a memory configured to store the machine learning algorithm.

8. The current sensor according to claim 2, wherein the sub-algorithms comprise an artificial neural network.

9. The current sensor according to claim 8, wherein each sub-algorithm comprises a multi-layer perceptron comprising a set of weights, a set of biases and an activation function.

10. The current sensor according to claim 9, wherein the activation function comprises a rectified linear unit function.

11. The current sensor according to claim 1, wherein the magnetic field sensing element comprises at least one of a Rogowski coil, a current transformer, a magnetic resistor sensor and a Hall sensor.

12. The current sensor according to claim 1, wherein the magnetic field sensing element is configured to sense a time varying magnetic field signal and output this signal to the circuit.

13. The current sensor according to claim 12, wherein the circuit comprises:
an amplifier configured to amplify the time varying magnetic field signal; and
a converter configured to convert the time varying magnetic field signal to obtain the first signal and output the first signal to the processor.

14. The current sensor according to claim 13, wherein the processor comprises:
an integrator, configured to integrate the first signal; and
a calculator configured to receive the integrated first signal and calculate the root mean squared value of the integrated first signal;
whereby the root mean squared value of the integrated first signal is the current value having an unknown error, and
wherein the calculator is further configured to output the current value having unknown error to the machine learning algorithm.

15. An apparatus comprising:
a current carrying conductor; and
a current sensor as claimed in claim 1.

16. The apparatus according to claim 15, wherein the apparatus is an electrical meter configured to measure an amount of current entering a load.

17. A method of monitoring a current value, the method comprising:
providing a current sensor as claimed in claim 1;
obtaining using the circuit coupled to the magnetic field sensing element, a first signal associated with a current value having an unknown error; and
executing, using a processor, a machine learning algorithm to generate an adjusted current value.

18. The method according to claim 17, wherein the machine learning algorithm comprises a plurality of sub-algorithms, each sub-algorithm being associated with a pre-determined range of current values; and the method further comprising selecting a sub-algorithm to be executed based on the current value.
